(19) United States
(12) Patent Application Publication
(10) Pub. No.: US 2025/0351286 A1
(43) Pub. Date: Nov. 13, 2025

(54) VEHICLE CONTROL APPARATUS

(71) Applicant: HYUNDAI MOBIS CO., LTD., Seoul (KR)

(72) Inventor: Su Ji KIM, Seongnam-si (KR)

(73) Assignee: HYUNDAI MOBIS CO., LTD., Seoul (KR)

(21) Appl. No.: 19/014,412

(22) Filed: Jan. 9, 2025

(30) Foreign Application Priority Data
May 7, 2024 (KR) 10-2024-0059557

(51) Int. Cl. H05K 7/14; B60R 16/023; H05K 5/03

(52) U.S. Cl. CPC H05K 7/1427; B60R 16/0239; H05K 5/03

(57) ABSTRACT

A vehicle control apparatus including: a housing including a base portion, a side wall configured to extend from the base portion and have a predetermined height with respect to the base portion, at one lateral side of the base portion, and a first assembling hole formed vertically at one end of an upper edge of the side wall; a circuit board that is held in the housing; a cover configured to be disposed vertically above the circuit board and be attached to the housing, and a second assembling hole formed at a position corresponding to the first assembling hole; a coupling member for coupling the housing and the cover together by vertically passing through the first assembling hole and the second assembling hole at a time; and a first protector formed in such a manner as to enclose at least part of one end of the coupling member while the housing and the cover are coupled together.

### CROSS-REFERENCE TO RELATED APPLICATION

This application claims the benefit of priority to Korean Patent Application No. 10-2024-0059557 filed in the Korean Intellectual Property Office on May 7, 2024 the entire contents of which are incorporated herein by reference.

### TECHNICAL FIELD

The present disclosure relates to a vehicle control apparatus.

### BACKGROUND

The content described below merely provides background information related to the present disclosure and does not constitute the related art.

A vehicle is equipped with a vehicle control apparatus which controls various systems and functions. For example, the vehicle control apparatus is capable of controlling an engine, a brake system, a transmission, a steering system, a safety system, and entertainment and convenience features.

An engine control apparatus contributes to maintaining optimum air/fuel ratio and vehicle performance by regulating the amounts of fuel and air drawn into the engine. A brake system control apparatus allows the vehicle to stably slow down by properly distributing the force of the brake to adjust to the speed of the vehicle, the ground conditions, and so on. A transmission control apparatus provides smooth acceleration and optimum transmission by regulating the operation of the transmission to adjust to the number of rotations of the engine and the driving conditions. A steering control apparatus controls the direction of the vehicle according to a steering input from the driver by regulating the steering angle and the torque. A safety system control apparatus protects vehicle passengers by controlling safety systems such as an airbag system, a lane keeping assist system (LKAS), or an advanced emergency braking system (AEBS). An entertainment and convenience feature control apparatus promotes convenience for passengers by controlling an entertainment system, a navigation device, or an air conditioner.

A vehicle control apparatus is assembled in such a way that, in an assembling process, a jig pin of an assembly jig is temporarily inserted into an assembly jig hole formed in one surface of a housing of the vehicle control apparatus. The assembly jig functions to fix and align the product in the process of assembling the product. The jig pin is a small pin used to hold the product in a precise position and direction, and the jig hole is a through-hole through which the jig pin can be inserted. The jig hole helps improve the accuracy and efficiency of the manufacturing process and maintain the quality of the product.

A vehicle control apparatus comes with a plurality of parts. To satisfy conditions for car vibration durability testing and BSR (buzz squeak rattle) testing, it is necessary to jointly fix a plurality of parts that apply to the vehicle control apparatus. For the joint fixing of a plurality of parts, a screw is used as a fixing member, in order to prevent buzzle, squeak, and rattle between parts, achieve satisfactory vibration performance, and ensure the durability of the control apparatus.

Existing control apparatuses produce foreign matter such as scraps or chip powder in the assembling of a screw. The foreign matter such as scraps or chip powder produced in the assembling of a screw gets into a circuit board within the vehicle control apparatus, leading to problems such as causing a short-circuit on circuit elements.

Moreover, moisture such as condensate and condensation generated from the vehicle can enter the inside of the vehicle control apparatus via a jig hole, which may result in a burn-out of elements of the circuit board.

### SUMMARY

A primary aspect of a vehicle control apparatus according to an embodiment of the present disclosure is to prevent a short-circuit of circuit elements by preventing foreign matter such as scraps or chip powder produced in the assembling of a screw from getting into a circuit board within the vehicle control apparatus in a process of jointly fixing a plurality of parts within the vehicle control apparatus.

Another aspect is to prevent a burn-out of circuit board elements which is caused when moisture such as condensate and condensation generated from the vehicle enters the inside of the vehicle control apparatus via a jig hole.

The problems to be solved by the present disclosure are not limited to the above-mentioned ones, and other problems not mentioned herein may be clearly understood by those skilled in the art from the description below.

A vehicle control apparatus comprising: a housing including a base portion, a side wall configured to extend from the base portion and have a predetermined height with respect to the base portion, at one lateral side of the base portion, and a first assembling hole formed vertically at one end of an upper edge of the side wall; a circuit board that is held in the housing; a cover configured to be disposed vertically above the circuit board and be attached to the housing, and a second assembling hole formed at a position corresponding to the first assembling hole; a coupling member for coupling the housing and the cover together by vertically passing through the first assembling hole and the second assembling hole at a time; and a first protector formed in such a manner as to enclose at least part of one end of the coupling member while the housing and the cover are coupled together.

### Advantageous Effects

A vehicle control apparatus according to an embodiment of the present disclosure has the effect of preventing a short-circuit of circuit elements by preventing foreign matter such as scraps or chip powder produced in the assembling of a screw from getting into a circuit board within the vehicle control apparatus in a process of jointly fixing a plurality of parts within the vehicle control apparatus.

Another effect is to prevent a burn-out of circuit board elements which is caused when moisture such as condensate and condensation generated from the vehicle enters the inside of the vehicle control apparatus via a jig hole.

### BRIEF DESCRIPTION OF THE DRAWINGS

FIG. 1 is an exploded perspective view of a vehicle control apparatus involving first and second embodiments of the present disclosure.

FIG. 2 is a perspective view of a vehicle control apparatus according to the present disclosure.

FIG. 3 is a partial enlarged view of a vehicle control apparatus according to the first embodiment of the present disclosure.

FIG. 4 is an assembled cross-sectional view of a vehicle control apparatus involving the first and second embodiments of the present disclosure.

FIG. 5 is a view showing a method of assembling a vehicle control apparatus according to the third embodiment of the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

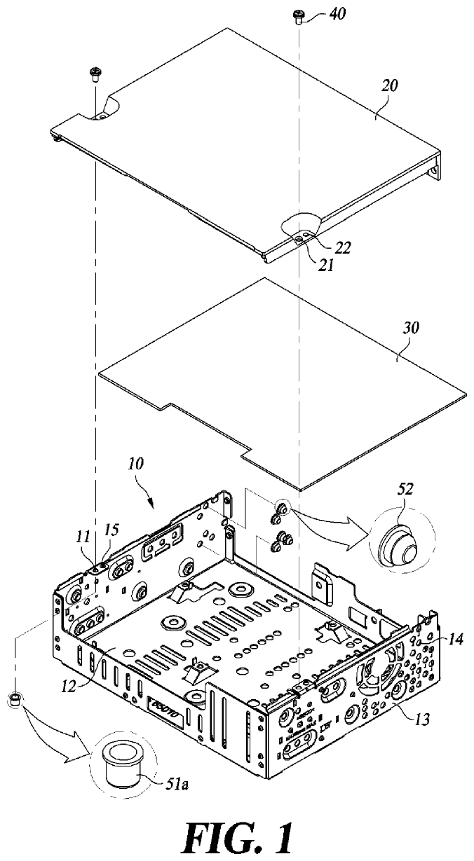

FIG. 1 is an exploded perspective view of a vehicle control apparatus involving first and second embodiments of the present disclosure.

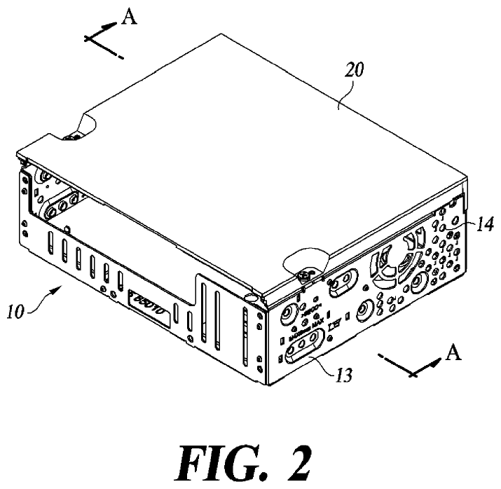

FIG. 2 is a perspective view of a vehicle control apparatus according to the present disclosure.

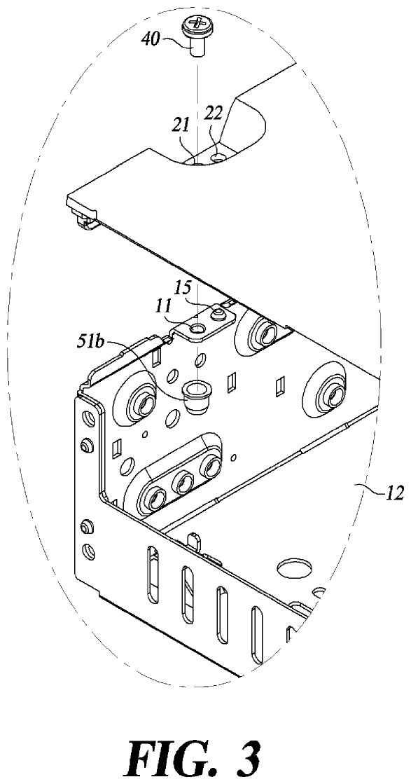

FIG. 3 is a partial enlarged view of a vehicle control apparatus according to the first embodiment of the present disclosure.

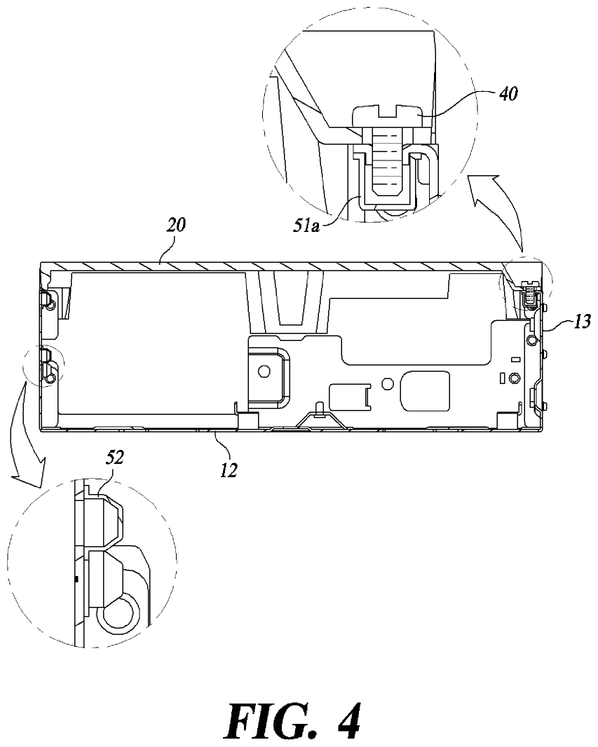

FIG. 4 is an assembled cross-sectional view of a vehicle control apparatus involving the first and second embodiments of the present disclosure.

Referring to FIGS. 1 through 4, the vehicle control apparatus according to the first embodiment of the present disclosure may include all or some of a housing 10, a circuit board 30, a cover 20, a coupling member 40, and a first protector 51a and 51b.

The housing 10 may include all or some of a base portion 12, a side wall 13, and a first assembling hole 11.

The base portion 12 corresponds to a lower surface of the housing 10. The circuit board 30 may be installed on at least part of a surface above the base portion 12 Parts, cables, etc., as well as the circuit board 30, may be installed on the surface above the base portion 12 The overall shape and size of the base portion 12 may correspond to parts installed thereon, such as the circuit board 30.

The side wall 13 is configured to have a predetermined height with respect to the base portion 12, at one lateral side of the base portion 12. The height of the side wall 13 may correspond to a configuration of parts installed within the housing 10, such as the circuit board 30. The side wall 13 may include an area that is curved and extends from one end of an upper edge of the side wall 13 in a direction perpendicular to the height direction which is perpendicular to one surface of the circuit board 30.

The first assembling hole 11 is a through-hole through which the coupling member 40 penetrates. The first assembling hole 11 may be formed heightwise at one end of the upper edge of the side wall 13. The first assembling hole 11 may be included in the area that is curved and extends from one end of the upper edge of the side wall 13 in a direction perpendicular to the height direction. The position, shape, and size of the first assembling hole 11 may correspond to a second assembling hole 21 and the coupling member 40 which will be described later. While FIG. 1 illustrates two first assembling holes 11, the present disclosure is not limited to what is shown in FIG. 1.

A controller (not shown) may include the circuit board 30 and various electronic components disposed on the circuit board 30. The controller may receive and handle information from a sensor or switch installed on each part of the vehicle by using various electronic components mounted on the circuit board 30, and may control various electrical functions of the vehicle.

The circuit board 30 is installed within the housing 10. Electronic components such as diodes may be mounted on the circuit board 30. For example, the circuit board 30 may be a printed circuit board (PCB).

The controller may perform functions like power management, signal processing, control signal generation, diagnosis, and error handling. The controller may perform the power management function for the vehicle by monitoring the voltage of a vehicle battery and regulating the electricity supply to the vehicle's electrical system. The various electronic components may process various signals related to engine condition, vehicle speed, etc. received from inside and outside the vehicle. The controller may control various features such as the engine, the brake, the air conditioner, and the windows based on processed information. The controller may perform functions of monitoring the operational status of the vehicle system, diagnosing an error, and taking proper action to correct the error, so as to maintain the safety and performance of the vehicle. While the above gives a description of exemplary functions of the controller, the present disclosure is not limited to this.

Various components may be disposed on the circuit board 30. The various components may perform different functions and control the vehicle system by interacting with one another. In the circuit board 30, a central processing unit CPU, a graphic processing unit GPU, various kinds of sensors, a microcontroller, a microprocessor, a memory, an analog-to-digital converter ADC, a digital-to-analog converter DAC, a power management integrated circuit PMIC, a signal processing circuit, and/or a protective circuit may be incorporated. This is an exemplary configuration, and the present disclosure is not limited to this.

As explained above, it is important to prevent foreign matter from getting into the circuit board since various electronic components are mounted on the circuit board 30 of the controller.

The cover 20 may be disposed vertically above the circuit board 30 and attached to the housing 10. As the cover 20 disposed vertically above the circuit board 30 held in the housing 10 is attached to the housing 10, the circuit board 30 may be protected.

The second assembling hole 21 may be formed vertically at a position on one surface of the cover 20 that corresponds to the first assembling hole 11. The second assembling hole 21 is a through-hole through which the coupling member 40 to be described later penetrates.

The second assembling hole 21 has a narrower cross-section from one side toward the other side along the height direction, and may be formed in a recessed portion where a lateral surface of the cover 20 is cut open. Here, one side of the cover 20 along the height direction refers to an upper side of the cover 20, and the other side of the cover 20 along the height direction refers to a side opposite to one side of the cover 20 along the height direction. The formation of the recessed portion may reduce the length of the coupling member 40, and may allow easy access from the coupling member 40 in the assembling process. While FIG. 1 illustrates two second assembling holes 21, the present disclosure is not limited to this.

The vehicle control apparatus according to the first embodiment may include a guide protrusion 15 formed adjacent to the first assembling hole 11 and a guide hole 22 formed adjacent to the second assembling hole 21 and corresponding to the guide protrusion 15. The guide protrusion 15 may be configured to have a predetermined height with respect to an area that is curved and extends in a direction perpendicular to the height direction from one end of the upper edge of the side wall 13. By further including the guide protrusion 15 and the guide hole 22, the housing 10 and the cover 20 may be pre-assembled quickly and precisely before the coupling member 40 is attached to the housing 10 and the cover 20. That is, the efficiency of the assembling process can be improved, and the assembly quality can be maintained.

The other side of the guide protrusion 15 along the height direction may have the same circular cross-section, and one side of the guide protrusion 15 along the height direction may be tapered at one end. Here, one side of the guide protrusion 15 along the height direction refers to a foremost side of the guide protrusion 15 that is first coupled to the guide hole 22. The other side of the guide protrusion 15 along the height direction refers to a side opposite to one side of the guide protrusion 15 along the height direction. Since one side of the guide protrusion 15 along the height direction is tapered at one end, the housing 10 and the cover 20 may be easily pre-assembled together.

The coupling member 40 is able to couple the housing 10 and the cover 20 together by vertically passing through the first assembling hole 11 and the second assembling hole 21 at the same time. The coupling member 40 may be, but not limited to, a machine type screw or a tapping type screw.

The first protector 51a and 51b may prevent scraps or chip powder from a chassis, caused when the coupling member 40 couples the housing 10 and the cover 20 together by vertically passing through the first assembling hole 11 and the second assembling hole 21 at a time, from getting into the circuit board 30. The first protector 51a and 51b may be formed in such a manner as to enclose at least part of one end of the coupling member 40 while the housing 10 and the cover 20 are coupled together. The first protector 51a and 51b may be assembled corresponding to the first assembling hole 11, under an area that is curved and extends from one end of the upper edge of the side wall 13 in a direction perpendicular to the height direction to enclose the first assembling hole 11. The assembling method may be, but not limited to, brazing, thermal fusion, etc.

The first protector 51a and 51b may have various shapes in order to perform the function of preventing foreign matter such as scraps or chip powder from getting into the circuit board 30.

The first protector 51a and 51b includes a flange portion and a receiving portion. The flange portion includes a surface that is attached to one area enclosing the first assembling hole 11.

In this specification, the first protector 51a and 51b is denoted by 51a or 51b in the drawings depending on the shape of one end of the other side along the height direction. The shape of the first protector 51a and 51b is not limited by the drawings, but may correspond to the shape of one end of the coupling member 40.

The first protector 51a whose receiving portion is cylindrical will be described first, and then the first protector 51b in which one end of the receiving portion is at least partially tapered will be described.

The receiving portion of the first protector 51a disclosed in FIGS. 1 through 4 may have the same circular cross-section, from one end of the first protector 51a along the height direction to the other side. Here, one side of the first protector 51 along the height direction refers to a side adjacent to the flange portion. The other side of the first protector 51a along the height direction refers to a side opposite to one side of the first protector 51a along the height direction.

The first protector 51b disclosed in FIG. 3 may be tapered at one end of the other side of the first protector 51b along the height direction.

The tapered shape of one end of the other side of the first protector 51b gives the housing 10 more internal space compared to when the first protector 51b has the same circular cross-section from one side of the first protector 51b along the height direction to the other side. The shape of the first protector 51a and 51b is not limited to these two examples. The first protector 51a and 51b may be formed to correspond in shape to one end of the coupling member 40.

Referring to FIGS. 1, 2, and 4, the vehicle control apparatus according to the second embodiment of the present disclosure may include all or some of a housing 10, a circuit board 30, a cover 20, and a second protector 52. The components according to the second embodiment of the present disclosure may be identical to the components according to the first embodiment, except for the components to be specifically described below, so a detailed description of the same parts will be omitted.

The side wall 13 may include a jig hole 14 on one surface through which a jig pin can be inserted. The number and configuration of jig holes 13 formed in the side wall 13 are not limited to what is illustrated in the drawings, but may correspond to the number and configuration of jig pins of an assembly jig.

The second protector 52 may prevent a burn-out of elements of the circuit board 30 which is caused when moisture such as condensate and condensation generated from the vehicle enters the inside of the vehicle control apparatus via the jig hole 14 of the control apparatus. The second protector 52 may be formed in such a manner as to enclose at least part of one end of the jig pin when the jig pin of the assembly jig is coupled to the jig hole 14, in the process of manufacturing the vehicle control apparatus. That is, the second protector 52 may be assembled corresponding to the jig hole 14 to one area of the side wall 13, which is an inner surface of the side wall 13, that encloses the jig hole 14. The assembling method may be, but not limited to, brazing, thermal fusion, etc.

The second protector 52 disclosed in FIGS. 1 and 4 includes a flange portion and a receiving portion. The flange portion includes a surface that is attached to one area enclosing the jig hole 14. The receiving portion may be shaped to be tapered at one end of a horizontal inner side perpendicular to the height direction. Here, the horizontal inner side refers to a side opposite to the flange portion attached to the side wall 13. The shape of the second protector 52 disclosed in FIGS. 1 and 4 is merely exemplary and is not limited to this. The second protector 52 may be formed to correspond in shape to one end of the jig pin.

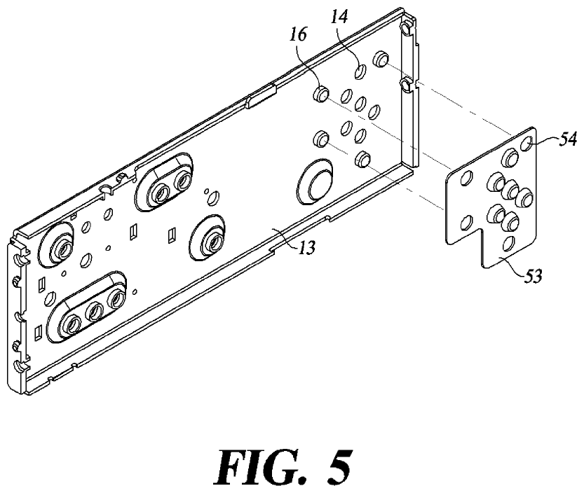

FIG. 5 is a view showing a method of assembling a vehicle control apparatus according to the third embodiment of the present disclosure.

Referring to FIGS. 1, 2, and 5, the vehicle control apparatus according to the third embodiment of the present disclosure may include all or some of a housing 10, a circuit board 30, a cover 20, and a third protector 53. The components according to the third embodiment of the present disclosure may be identical to the components according to the first and second embodiments, except for the components to be specifically described below, so a detailed description of the same parts will be omitted.

The side wall 13 may include a plurality of jig holes 14.

The third protector 53 may be constructed of a single plate including a plurality of dome structures corresponding in number and configuration to the plurality of jig holes 14. With the single plate, the assembling process may be simplified compared to joining a protector to each of the plurality of jig holes 14 on an inner side of the side wall 13, thereby improving the efficiency of the manufacturing process. The side wall 13 and the third protector 53 may be joined together by brazing, thermal fusion, etc., but not limited to these.

The vehicle control apparatus according to the third embodiment may further include an assembling protrusion 16 and a third assembling hole 54.

The assembling protrusion 16 may be formed on an inner side of the side wall 13 so as be adjacent to the plurality of jig holes 14. The assembling protrusion 16 may pass through and be coupled to the third assembling hole 54 formed on one surface of the third protector 53 which will be described below.

The third assembling hole 54 may be formed on one surface of the third protector 53, corresponding to the assembling protrusion 16. The side wall 13 and the third protector 53 may be joined together by passing the assembling protrusion 16 through the third assembling hole 54. By doing so, they can be joined more easily compared to joining them by thermal fusion.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

What is claimed is:

1. A vehicle control apparatus comprising:
a housing including a base portion, a side wall configured to extend from the base portion and have a predetermined height with respect to the base portion, at one lateral side of the base portion, and a first assembling hole formed vertically at one end of an upper edge of the side wall;
a circuit board that is positioned in the housing;
a cover configured to be disposed vertically above the circuit board and be attached to the housing, and a second assembling hole formed at a position corresponding to the first assembling hole;
a coupling member for coupling the housing and the cover together by vertically passing through the first assembling hole and the second assembling hole; and
a first protector configured to enclose at least part of one end of the coupling member while the housing and the cover are coupled together.

2. The vehicle control apparatus of claim 1, wherein the first protector is assembled corresponding to the first assembling hole, under an area that is curved and extends from one end of the upper edge of the side wall in a direction perpendicular to a height direction to enclose the first assembling hole.

3. The vehicle control apparatus of claim 1, further comprising a guide protrusion positioned adjacent to the first assembling hole and a guide hole positioned adjacent to the second assembling hole and corresponding to the guide protrusion.

4. The vehicle control apparatus of claim 1, wherein the first protector has a same circular cross-section from one side toward another side along a height direction.

5. The vehicle control apparatus of claim 1, wherein the first protector is tapered at one end along a height direction on an opposite side.

6. A vehicle control apparatus comprising:
a housing including a base portion, a side wall configured to extend from the base portion and have a predetermined height with respect to the base portion, at one lateral side of the base portion, and a jig hole formed on one surface of the side wall;
a circuit board that is positioned in the housing;
a cover disposed above the circuit board and attached to the housing; and
a second protector configured to enclose at least part of a jig pin passing through the jig hole.

7. The vehicle control apparatus of claim 6, wherein the second protector is shaped to correspond to one end of the jig pin.

8. The vehicle control apparatus of claim 6, wherein the second protector is joined to an inner surface of the side wall, that encloses the jig hole by thermal fusion.

9. A vehicle control apparatus comprising:
a housing including a base portion, a side wall configured to extend from the base portion and have a predetermined height with respect to the base portion, at one lateral side of the base portion, and a plurality of jig holes formed on one surface of the side wall;
a circuit board that is positioned in the housing;
a cover disposed above the circuit board and attached to the housing; and
a third protector including a plurality of dome structures respectively corresponding in position to a plurality of jig pins passing through the plurality of jig holes, respectively,
wherein the third protector is constructed of a single plate, and each of the plurality of dome structures is configured to enclose at least part of each of the plurality of jig pins.

10. The vehicle control apparatus of claim 9, wherein the side wall includes an assembling protrusion on an inner side of the side wall adjacent to the plurality of jig holes, the third protector includes a third assembling hole configured to receive the assembling protrusion, and the side wall and the third protector are joined together by passing the assembling protrusion through the third assembling hole.
